(19) United States
(12) Patent Application Publication
(10) Pub. No.: US 2007/0052433 A1
(43) Pub. Date: Mar. 8, 2007

(54) Coaxial probe, method for production thereof, and device for measuring in the near electromagnetic field on systems at a submicrometric distance

(75) Inventors: Jean-Louis Carbonero, Crolles (FR); Maxime Marchetti, Bastia (FR); Michel Castagne, Clapiers (FR)

Correspondence Address: SEED INTELLECTUAL PROPERTY LAW GROUP PLLC, 701 FIFTH AVENUE, SUITE 5400, SEATTLE, WA, 98104-7092, US

(73) Assignees: STMicroelectronics S.A., Montrouge (FR); Centre National De La Recherche Scientifique, Paris (FR)

(21) Appl. No.: 11/430,192

(22) Filed: May 8, 2006

(30) Foreign Application Priority Data
May 9, 2005 (FR) 05 04634

(51) Int. Cl. G01R 31/02

(52) U.S. Cl. 324/754

(57) ABSTRACT

A coaxial probe for near-field measurements including a connection wire of which a first end is connected to a connector, the connection wire covered with a dielectric substrate and a shield to form a waveguide. The probe has a diameter D equal to at least 300 micrometers.

### BACKGROUND OF THE INVENTION

1. Field of the Invention

This invention relates to the field of local probe microscopy, also called near-field microscopy or SPM for Scanning Probe Microscope, including that of near electromagnetic field microscopy, and, more specifically, to a probe of micrometric size and the method for production thereof, a position measuring device, and a system for movement and for acquisition of electromagnetic data and the like applied to submicrometric systems.

2. Description of the Related Art

Currently, the tendency is toward miniaturization of electronic devices and toward increasing operating frequencies. The integration surfaces are being reduced and the number of basic components present on the chip is increasing.

These basic components, so-called passive (for example, capacitors, connection tracks) or active (for example, transistors), are interleaved with respect to one another and are placed at distances sometimes much smaller than the wavelength, referred to as a subwavelength, from one another, promoting the occurrence of the coupling phenomenon.

Indeed, a component of subwavelength size transmits progressive waves that can be measured in a far field located at a distance greater than or equal to the wavelength λ of the component, and evanescent waves remaining confined near the component, in a so-called near field. The amplitude of the evanescent wave typically decreases in exponential form as it moves away from the component, and does not have a medium energy. The amplitude of these evanescent waves is already significantly reduced at a distance equal to the wavelength λ of the component.

A basic component located in the near-field zone of an adjacent component is thus subjected to the influences of the evanescent waves of said adjacent component.

Near electromagnetic field mapping is therefore useful in the design of microwave circuits.

Due to the confinement of the evanescent waves very close to the component, it is necessary to perform measurements directly in the near-field zone and as close as possible to the component, for example, at distances less than or equal to λ/2π from the component. The intensity and resolution can only be enhanced by extremely small distances.

Currently, there are various techniques for near-field measurements, which make it possible to collect physical quantities essentially related to the properties of the materials of the sample to be analyzed, and which are not always very easy to implement. Among these techniques, the following can be cited:

transmission microscopy, which makes it possible to determine the local conductivity at the surface of the circuits, but requiring sophisticated equipment;

near-field microwave microscopy using electrooptical methods requiring the use of equipment of which the properties change upon exposure to an electromagnetic field;

SQUID (Super Quantum Interference Device) microscopy using cryogenics;

resonant cavity or line microwave microscopy enabling conductivity or resistivity to be measured.

### BRIEF SUMMARY OF THE INVENTION

The disclosed embodiments of the invention provide a near electromagnetic field measurement device and method that are easy to implement, not requiring sophisticated equipment.

Due to its good sensitivity and electrical properties, a coaxial antenna is normally used for microwave acquisition.

However, the usual means for collecting the electromagnetic field using an antenna having a size of λ/2 are ineffective for detecting the electromagnetic behavior of samples having a subwavelength size, in particular due to the size of the antenna. This could be compared to the Rayleigh-Abbe criterion used in optical microscopy, known to a person skilled in the art, whereby the behavior of an electromagnetic microwave can be comparable to that of a light wave.

In addition, the measurements are generally performed at large distances from the sample, on the order of one millimeter or even one centimeter.

The use of a coaxial antenna having a large diameter in radiated microwave field sensing, for example 3 millimeters, makes it possible to collect more energy, but this collected energy also integrates the high spatial frequencies associated with the details of the radiation end and therefore enables only little information on a localized source to be obtained. By contrast, an antenna having a small diameter, for example 600 micrometers, integrates fewer high spatial frequencies, but the energy collected is lower, thus reducing the intensity of the magnitude measured.

One embodiment of the invention makes it possible to perform a near-field measurement as close as possible to the sample, with a good resolution.

International application no. WO 2004/057355 (Shvets, Kantor), while proposing a device for testing a high-frequency circuit using an antenna, has the disadvantage of requiring the probe to be changed for the evaluation of the probe-sample distance and for the test at a particular frequency. This device therefore requires two steps and two different probes for the acquisition of the height and for the acquisition of the field. Moreover, as the antenna is adapted to a particular frequency, it is also necessary to change antennas when measurements are to be performed at a different frequency.

Thus, one embodiment of the invention provides a measurement and/or test device including a coaxial probe having a micrometric size, and enabling the submicrometric positioning (<0.5 μm) of the probe on the sample so as to enhance the spatial and frequential resolution.

Another embodiment of the invention provides probe enabling measurements to be performed in a wide frequency band, for example for frequencies at least above 100 MHz, not requiring the probe to be changed.

Another embodiment of the invention provides a device sensitive to one or more physical quantities.

These embodiments, among others, are achieved by the invention, which includes a method for producing a coaxial probe including steps consisting of:

connecting, to a connector, a first end of an electrical connection wire having a diameter of at least 100 micrometers;

performing a chemical attack operation on a second end of the connection wire, opposite said first end, so as to shape said second end, preferably into a conical point;

depositing a dielectric substrate around said connection wire and over its entire length so as to create a waveguide for said probe, with the thickness of the deposition being at least equal to 100 micrometers;

depositing a metal layer around said connection wire and over its entire length so as to form a shield for said probe having a thickness of at least 30 micrometers; and

removing the metal layer surrounding said probe point on a working portion thereof so as to expose it, with said working portion having a length of at least 100 micrometers.

The deposition of the dielectric substrate is advantageously performed by a dip/coating technique.

The shield is preferably obtained by an electrolytic method.

According to a preferred embodiment, the metal layer is removed from the working portion of the probe by reverse electrolysis.

The coaxial probe mentioned above acts as a waveguide in its central portion.

According to the invention, the probe has a diameter D at least equal to 300 micrometers.

The probe advantageously has a conical point located at a second end of the connection wire, opposite the first end.

The waveguide between the two ends is preferably produced with a dielectric substrate deposited on the central core, and has a thickness of at least 100 micrometers.

The shield is preferably deposited on the dielectric substrate and has a thickness of at least 600 nanometers.

The conical point preferably has no shield over a length L at least equal to 100 micrometers.

The invention also relates to a device for measuring the position and/or distance between the probe and the integrated circuit being tested, including:

a probe placed perpendicularly with respect to a working surface,

an oscillation circuit for causing the probe to oscillate in a direction parallel to the working surface.

According to another aspect of the invention, the device includes a probe having the features of the probe described above or produced according to the aforementioned production method.

The oscillation circuit advantageously includes a tuning fork and a circuit for exciting the tuning fork, with the probe being attached to an arm of the tuning fork.

The device preferably includes detection means for measuring the distance between the probe and the working surface, which detection means generate a first signal representing a physical magnitude in relation to the distance between the probe and the working surface.

The device preferably includes a circuit for acquiring a signal sensed by the probe point and transmitted to the acquisition circuit via the connector, which acquisition circuit generates a second signal representing said sensed signal.

The device preferably includes a processing and/or control circuit receiving said first and second signals, and generating a third signal to control the approach mechanism.

According to a specific embodiment of the invention, the detection circuit implement a physical magnitude by a technique for detecting shear forces occurring between the working surface and the probe. The physical magnitude is dependent on the distance between the probe and the working surface.

The shear forces increase in a manner inversely proportional to the distance between the probe and the working surface. The result is therefore that the amplitude of the oscillation of the position sensor and the associated probe decreases under the same conditions.

The invention also relates to:

an approach mechanism for selectively moving the probe and the position sensor,

a device for acquiring the electromagnetic information, and

a device for acquiring the position information.

According to an embodiment, the approach mechanism for moving the probe and the position sensor consist of:

first movement means for moving the probe along a first axis X parallel to the working surface,

second movement means for moving the probe along a second axis Y parallel to the working surface and perpendicular to the first axis X and,

third movement means for moving the probe along a third axis Z perpendicular to the working surface, and with a first movement accuracy.

According to the invention, the device includes fourth movement means for selectively imparting, on the probe, a movement along the third axis Z of which the position or movement is controlled with an amplitude superior to the first accuracy.

According to another specific embodiment of the invention, the acquisition device includes an amplifier for amplifying the signal sensed by the probe.

The device can also include a microwave generator for injecting microwave signals into passive-type samples.

The acquisition device can also include an isolator in order to eliminate waves reflected in one direction of travel and in the other, which isolator is placed between the probe and the amplifier.

The device can also include a network analyzer such as a device for processing the microwave signal, as well as a spectrum analyzer or an oscillator.

In accordance with another embodiment of the invention, a probe is provided that includes an electrically conductive core, a dielectric substrate covering the core, and a shield covering the substrate, the probe having a diameter of at least 300 micrometers. Ideally, the probe has a first end in which the core has a conical point that is not covered by dielectric and shield over a length of at least 100 micrometers. Together the core, dielectric, and shield form a coaxial wave guide.

In accordance with another embodiment of the invention, a system for probing an integrated circuit is provided that includes a probe comprising an electrically conductive core, a dielectric substrate covering the core, and a shield covering the substrate, the probe having a diameter of at least 300 micrometers, an oscillator adapted to oscillate the probe over the integrated circuit, and an actuator adapted to move the probe across the surface of the integrated circuit and to move the probe along an axis perpendicular to the surface of the integrated circuit.

In accordance with another aspect of the foregoing embodiment, the oscillator comprises a tuning fork and the probe is attached to an arm of the tuning fork.

In accordance with another aspect of the foregoing embodiment, the system includes a detector adapted to evaluate a distance between the probe and the integrated circuit, the detector configured to generate an output responsive to movement of the probe over the integrated circuit, and a signal processor coupled to the detector and configured to receive an output from the detector and to generate an output signal responsive thereto.

In accordance with another aspect of the foregoing embodiment, the system includes a control circuit receiving output from the detector and the signal processor and configured to generate a control signal that is output to the actuator to control movement of the probe relative to the integrated circuit.

### BRIEF DESCRIPTION OF THE SEVERAL VIEWS OF THE DRAWINGS

These features and advantages among others of the present invention will be described in greater detail in the following non-limiting description of a preferred embodiment of the invention in relation to the appended figures, wherein:

FIG. 1 shows a diagram of the coaxial probe according to the invention;

FIG. 2 shows a block diagram of a specific embodiment of the measuring and/or testing device according to the invention; and

FIG. 3 shows three scanning modes of the probe.

### DETAILED DESCRIPTION OF THE INVENTION

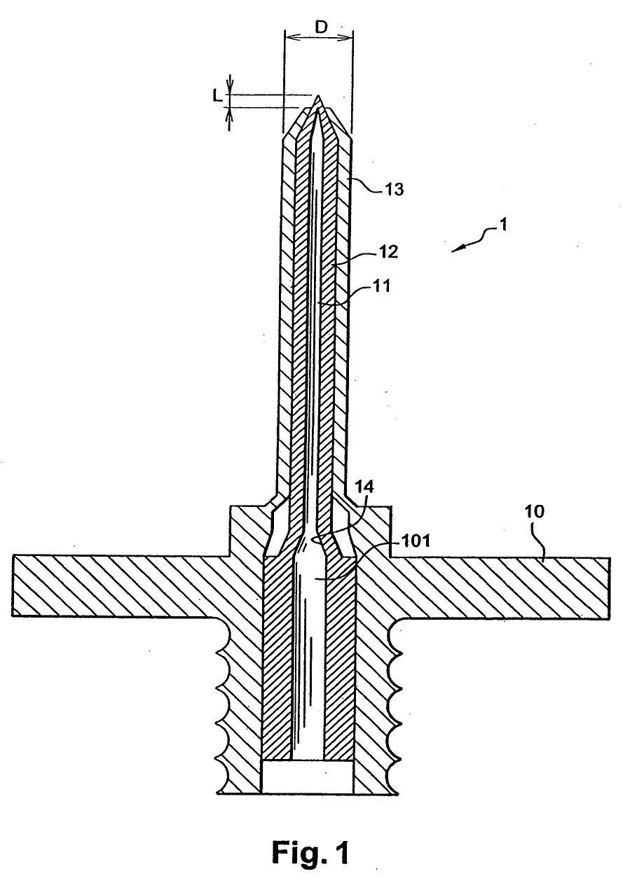

FIG. 1 shows a diagram of the probe 1 according to the invention. This probe 1 has the feature of being of micrometric size, with a diameter D not exceeding 150 μm. It also includes a connection wire 11, forming the central core of the probe, connected to a connector, for example an SMA-type connector 10 (SubMiniature version A), covered, for example, by a dielectric substrate layer 12, and a shield 13 so as to thus form a waveguide 11, 12, 13.

Such sizes require a new method for producing such a probe.

Thus, the method for producing the probe 1 of micrometric size involves various methods for depositing layers of materials. The various methods are based on methods of chemical attack of a connection wire 11, forming the central core of the probe 1, in order to form a point or apex, a dip/coating technique in order to deposit the dielectric substrate 12, as well as thin film metal deposition techniques such as thermal evaporation or electrolytic depositions so as to form the shield 13, thus forming a waveguide. The probe 1 is secured to the connector 10, and the probe 1 thus produced has diameters ranging from 40 μm to 200 μm. The end of the probe 1 has a conical structure and is stripped of several micrometers by chemical attack so as to form a working point.

Thus, a method for producing the probe 1 may consist of the following steps:

connection of the connection wire 11, for example, a gold (Au) wire having a diameter of 25 μm and a length of 2 cm, to the central conductor of the SMA (SubMiniature version A) connector 10, for example, using, for example, a conductive coating 14 so as to ensure the electrical contact and the attachment of the connection wire 11 to the central conductor of a connector 101;

formation of the conical point of the probe 1 by chemical attack with potassium iodide;

initiating the waveguide 11, 12, 13 production by dipping the connection wire 11 in a tub containing the dielectric substrate 12, for example a resin, so as to cover the connection wire 11 of said dielectric substrate 12, with the thickness of the deposition ranging from 1 μm to 50 μm, for example 30 μm;

shielding of the probe 1 by first performing thermal evaporation of copper (Cu) on the dielectric substrate 12 thus deposited so as to form the electrical ground contact and then enable an electrolysis operation so as to finish the shield, which shield has a minimum thickness of 600 nm; and

performance of a reverse electrolysis operation so as to remove the shield over a length L of the conical point of the probe 1 so as to form a working point of a length L ranging between 1 μm and 100 μm.

The probe thus produced has acceptable sizes for limiting the integration of high spatial frequencies, and enables measurements to be performed over a wide frequency band.

However, a probe of micrometric size is not enough. As the evanescent wave remains confined very close to the sample to be analyzed, it is necessary to place the probe directly in the near-field zone as close as possible to the sample in order to detect this wave. The evanescent wave is detected by the conversion of the evanescent wave into a traveling wave in the probe of largely subwavelength size.

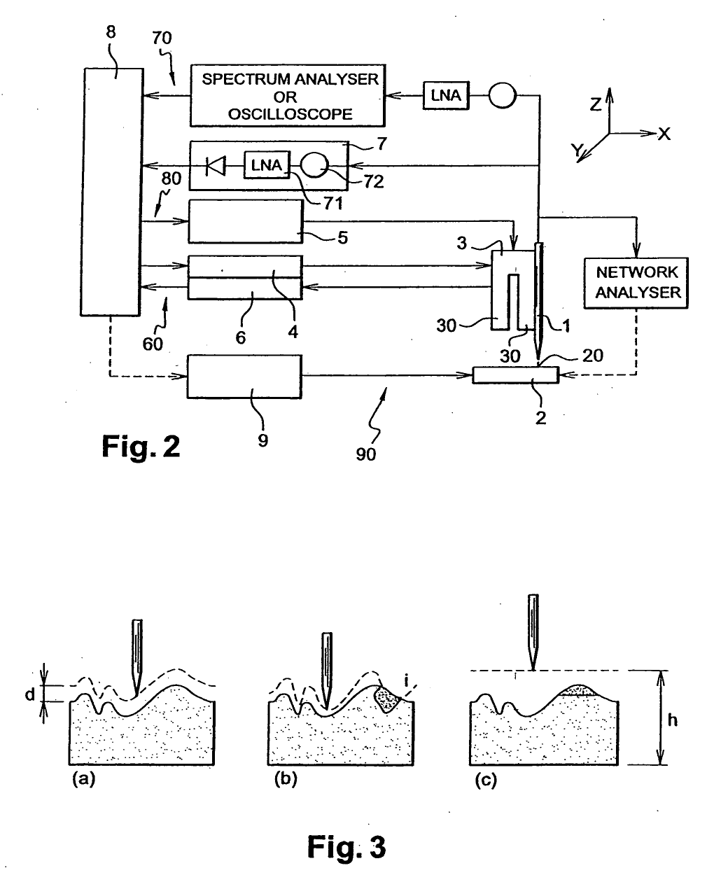

FIG. 2 shows a block diagram of a specific embodiment of the measuring and/or testing device using the probe having the aforementioned features, and making it possible to evaluate the distance between the point of the probe and the sample, and to process a high-frequency signal proportional to the data collected in the near field by the point of the probe.

This device includes:

the probe 1 placed perpendicularly with respect to a working surface 2;

oscillation means (3, 4) for mechanically oscillating the probe in a direction parallel to the working surface 2;

an approach mechanism 5 for selectively moving the probe 1;

detection means 6 for detecting the signal proportional to the distance between the point of the probe 1 and the sample placed on the working surface 2;

means for acquiring 7 a signal from the probe 1;

processing and/or control means 8; and

a microwave generator 9 or a network analyzer.

All of the elements are described in detail below.

The probe 1 used has the features of the probe defined above with respect to FIG. 1. It is therefore of micrometric size and enables the near electromagnetic field to be detected.

The oscillation means 3 and 4 enable the probe 1 to be mechanically vibrated at a given frequency. There is a plurality of methods:

if the movement of the probe 1 is achieved by piezoelectric elements (for example, tubes, plates), then the movement device can act directly as an excitation source by modulating its supply with an alternative voltage. Additional quadrant electrode sections are then necessary for the excitation and the detection of the amplitude of the point;

a solid piezoelectric element, to which the probe is secured, can also be used. The piezoelectric element is supplied by an alternative voltage and the mechanical vibrations are detected either mechanically or optically;

the probe can also be secured directly to a piezoelectric element in the form of a tuning fork 3. The excitation of the tuning fork 3 at its resonance frequency causes the probe 1 to vibrate at the resonance frequency of the mechanical probe 1/tuning fork 3 system.

It is this last solution that is used in the specific embodiment of the measuring device shown in FIG. 2. Indeed, it enables the weight the microscope head to be minimized. More specifically, the tuning fork 3 is of the quartz clock tuning fork-type, which has the advantage of having very reduced bulk and makes it possible to use the method described in “K. Karai, R. Grober, Piezo-electric tuning-fork tip sample distance control for near-field optical microscopes, Ultramicroscopy, Elsevier, May 1995” in order to detect shear forces existing between the end of the probe 1 and the sample. In addition, the operating principle of a quartz clock tuning fork is described very well in the work “D. Courjon, C. Bainier. Le champ proche optique théorie et application. Edition Springer, 2001”.

The tuning fork 3 is excited by excitation means 4. These excitation means can be mechanical, for example, an additional piezoelectric element, or electronic, by integrating the tuning fork 3 in a resonant circuit.

As the probes are secured to one of the arms 30 of the tuning fork 3, the interaction of the probe point with the surface of the sample dampens the oscillation amplitude of the point.

Thus, as the tuning fork 3, having a theoretical resonance frequency f equal to around 32768 Hz, is subjected to a sinusoidal excitation voltage, for example between 1 mV and 10 mV, the force occurring between the probe point and the sample is measured by observing the amplitude or phase shift of the current that passes through it.

Since the amplitude decreases as the probe-sample distance is reduced, it is possible to determine the position of the probe 1.

Thus, by choosing to use a tuning fork 3 coupled to the probe 1, the probe oscillation means (3, 4), as well as the means 6 for detecting the shear force which deliver a first signal 60 in relation to the distance between the probe point and the sample, are provided.

The approach mechanism 5 includes:

first movement means for moving the probe 1 along a first axis X parallel to the working surface 2,

second movement means for moving the probe 1 along a second axis Y parallel to the working surface 2 and perpendicular to the first axis X and,

third movement means for moving the probe 1 along a third axis Z perpendicular to the working surface 2.

These three movement means are, for example, stepper motors, allowing for a minimum step of 100 nm.

The approach mechanism 5 also includes fourth movement means for selectively imparting, on the probe, a movement along the third axis Z. These last movement means are, for example, a piezoelectric motor allowing for movements smaller than the minimum step enabled by the first, second and third movement means.

The acquisition means 7 make it possible to convey the information propagated through the waveguide 11, 12 and 13 of the probe 1.

In the preferred embodiment of the invention, the acquisition means 7 include an amplifier 71, an isolator 72 and a Schottky diode 73.

The isolator 72 placed between the probe 1 and the amplifier 71 makes it possible to eliminate the waves reflected in one direction and in the other.

The amplifier 71 makes it possible to recover and amplify a signal detected 20 by the probe point, which is transmitted thereto via the connector 10 and through the isolator 72, and to guide it to the diode 73. The power of the detected signal 20 collected at the level of the connector 10 is generally very low, and is of course dependent on the power transmitted by the sample, as well as the size of the probe 1 and the distance between the probe point and the sample. The amplifier used in this specific embodiment is a low noise amplifier (LNA) having, for example, a noise factor of 4.5 dB in the frequency band 7 GHz to 12 GHz.

The Schottky diode 73 makes it possible to obtain a continuous voltage of which the amplitude is dependent on that of the signal transmitted by the amplifier 71. It generates a second adjusted continuous signal 70.

The processing and/or control means 8 process the first and second signals (60, 70) respectively from the detection means 6 and the acquisition means 7. As the first signal 60 represents the distance between the probe point and the sample, and the second signal 70 represents the power of the electromagnetic signal radiated by the sample, it is possible to reconstruct a three-dimensional image of the near electromagnetic field.

The first signal 60 also makes it possible, using a control system, to position the probe 1 by means of the approach mechanism 5.

The means for processing the signal proportional to the electromagnetic field collected by the probe 1 can also be an oscilloscope or a spectrum or network analyzer.

The microwave generator makes it possible to inject a third signal 90 into a passive-type sample. It can also be controlled by the processing and/or control means 8.

FIG. 3 shows three main modes for scanning by the probe 1 in the vicinity of the sample.

The first case (a), constant distance scanning, consists of moving and holding the probe point at a distance d very close to the surface of the sample, typically several nanometers, along a trajectory similar to the relief. This is a technique that requires the installation of a control system, and the advantage of this type of movement is that it preserves the end of the probe point because no contact with the surface is possible.

The second case (b), constant intensity scanning, also uses a control system for maintaining the intensity of the magnitude of the interaction with the evanescent wave equal to a predetermined set value.

The third case (c), constant height scanning, consists of maintaining the probe at a given height h above the middle plane of the surface of the sample. This requires surfaces with a small incline or a correction of the planarity of the sample during the scanning, or surfaces with small reliefs.

All of the above U.S. patents, U.S. patent application publications, U.S. patent applications, foreign patents, foreign patent applications and non-patent publications referred to in this specification and/or listed in the Application Data Sheet, are incorporated herein by reference, in their entirety.

From the foregoing it will be appreciated that, although specific embodiments of the invention have been described herein for purposes of illustration, various modifications may be made without deviating from the spirit and scope of the invention. Accordingly, the invention is not limited except as by the appended claims.

1. A method for producing a coaxial probe, comprising:
connecting to a connector a first end of an electrical connection wire having a diameter of at least 100 micrometers;
performing a chemical attack operation on a second end of the connection wire, opposite said first end, so as to shape said second end into a conical point;
depositing a dielectric substrate around said connection wire and over its entire length so as to create a waveguide for said probe, with the thickness of the deposition being at least equal to 100 micrometers;
depositing a metal layer around said connection wire and over its entire length so as to form a shield for said probe; and
removing the metal layer surrounding said probe point on a working portion thereof so as to expose it, with said working portion having a length L of at least 100 micrometers.

2. The method according to claim 1 wherein the dielectric substrate is deposited by means of a dip/coating technique.

3. The method according to claim 1 wherein the shield is obtained by thermal evaporation followed by an electrolytic process.

4. The method according to claim 1 wherein the metal layer is removed from the working portion of the probe by reverse electrolysis.

5. A coaxial probe for near-field measurements, comprising:
a connection wire of which a first end is connected to a connector, said connection wire covered with a dielectric substrate and a shield, forming a waveguide,
the probe having a diameter of at least 300 micrometers.

6. The probe according to claim 5, comprising a conical point located at a second end of the connection wire, opposite the first end.

7. The probe according to claim 5 wherein the dielectric substrate has a thickness equal to at least 100 micrometers.

8. The probe according to claim 5 wherein the shield is deposited on the dielectric substrate so as to form the waveguide and has a thickness equal to at least 600 nanometers.

9. The probe according to claim 6 wherein the conical point has no shield over a length L equal to at least 100 micrometers.

10. A device for measuring and/or testing an integrated circuit, comprising:
a probe placed perpendicularly with respect to a working surface;
oscillation means for causing the probe to oscillate in a direction parallel to the working surface;
an approach mechanism for selectively moving the probe, comprising:
first movement means for moving the probe along a first axis X parallel to the working surface;
second movement means for moving the probe along a second axis Y parallel to the working surface and perpendicular to the first axis X and;
third movement means for moving the probe along a third axis Z perpendicular to the working surface, and with a first movement accuracy; and
fourth movement means for selectively imparting on the probe a movement along the third axis Z of which the amplitude is controlled with an amplitude superior to the first accuracy.

11. The device according to claim 10 wherein the oscillation means include a tuning fork and means for exciting said tuning fork, wherein the probe is attached to an arm of the tuning fork.

12. The device according to claim 10, comprising detection means for evaluating the distance between the probe and the working surface, which detection means generate a first signal representing a physical quantity in relation to the distance between the probe and the working surface.

13. The device according to claim 10, comprising means for acquisition of a signal detected by the probe point and transmitted to said acquisition means via the connector, wherein said acquisition means generate a second signal representing said detected signal.

14. The device according to claim 10, comprising processing means receiving said first and second signals, and generating a third signal to control the approach mechanism.

15. The device according to claim 10, comprising a microwave generator for injecting microwave signals into passive-type samples.

16. The device according to claim 12 wherein the detection means implement a technique for detecting shear forces occurring between the working surface and the probe, wherein said physical magnitude is dependent on the excitation amplitude of the probe which decreases as the distance between the probe and the working surface decreases.

17. The device according to claim 13 wherein the acquisition means include an amplifier for amplifying the signal detected by the point of the probe.

18. The device according to claim 13 wherein the acquisition means include an isolator for eliminating waves reflected in one direction of travel and in the other, wherein the isolator is placed between the probe and the amplifier.

19. A probe, comprising:
an electrically conductive core;
a dielectric substrate covering the core; and
a shield covering the substrate, the probe having a diameter of at least 300 micrometers.

20. The probe of claim 19 wherein the substrate is at least 100 micrometers thick and the shield has a thickness of at least 600 nanometers, and the core, dielectric, and shield form a coaxial wave guide.

21. The probe of claim 20 wherein the probe comprises a first end in which the core has a conical point that is not covered by dielectric and shield over a length of at least 100 micrometers.

22. A system for probing an integrated circuit, comprising:
a probe comprising an electrically conductive core, a dielectric substrate covering the core, and a shield covering the substrate, the probe having a diameter of at least 300 micrometers;
an oscillator adapted to oscillate the probe over the integrated circuit; and
an actuator adapted to move the probe across the surface of the integrated circuit and to move the probe along an axis perpendicular to the surface of the integrated circuit.

23. The system of claim 22, wherein the oscillator comprises a tuning fork, and the probe is attached to an arm of the tuning fork.

24. The system of claim 22, further comprising:
a detector adapted to evaluate a distance between the probe and the integrated circuit, the detector configured to generate an output responsive to movement of the probe over the integrated circuit; and
a signal processor coupled to the detector and configured to receive an output from the detector and to generate an output signal responsive thereto.

25. The system of claim 24, further comprising a control circuit receiving output from the detector and the signal processor and configured to generate a control signal that is output to the actuator to control movement of the probe relative to the integrated circuit.

26. The system of claim 22 wherein the signal processor comprises an amplifier for amplifying output from the detector, an isolator adapted to eliminate waves reflected in one direction of travel and coupled between the probe and the amplifier.
